(19) United States
(12) Patent Application Publication
(10) Pub. No.: US 2003/0024471 A1
(43) Pub. Date: Feb. 6, 2003

(54) Fabrication of semiconductor structures and devices forms by utilizing laser assisted deposition

(75) Inventors: Albert Alec Talin, Scottsdale, AZ (US); Jay A. Curless, Tempe, AZ (US); Ravindranath Droopad, Chandler, AZ (US); Joyce Yamamoto, Chandler, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL

(21) Appl. No.: 09/921,910

(22) Filed: Aug. 6, 2001

(51) Int. Cl. H01L 21/00

(52) U.S. Cl. 117/92; 438/3

(57) ABSTRACT

Semiconductor structures are provided with high quality epitaxial layers of monocrystalline materials grown overlying monocrystalline substrates such as large silicon wafers by forming a compliant substrate for growing the monocrystalline layers. An accommodating buffer layer comprises a layer of monocrystalline oxide spaced apart from a silicon wafer by an amorphous interface layer of silicon oxide. The accommodating buffer layer is lattice matched to both the underlying silicon wafer and an overlying monocrystalline material layer. With laser assisted fabrication, a laser energy source is used to preclean the accommodating buffer layer, to excite the accommodating buffer layer to higher energy to promote two-dimensional growth, and to amorphize the accommodating buffer layer, without requiring transport of the semiconductor structure from one environment to another. When chemical vapor deposition is utilized, the laser radiation source can be employed to crack volatile chemical precursors while selectively heating the growth substrate to enable selective deposition.

### FIELD OF THE INVENTION

This invention relates generally to semiconductor structures and devices and their fabrication using decomposition of precursors, and more specifically to semiconductor structures and devices that include a monocrystalline material layer comprised of semiconductor material, compound semiconductor material, and/or other types of material such as metals and non-metals using a compliant substrate.

### BACKGROUND OF THE INVENTION

Semiconductor devices often include multiple layers of conductive, insulating, and semiconductive layers. In many instances, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals. However, advantages of such structures may be lost if impurity's, such as those which reduce electron mobility or photo activity are not satisfactorily controlled.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, certain device structures;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure;

FIGS. 13-16 illustrate a probable molecular bonding structure of the device structures illustrated in FIGS. 9-12;

FIGS. 17-20 illustrate schematically, in cross-section, the formation of still another device structure; and

FIGS. 21-23 illustrate schematically, in cross-section, the formation of yet another device structure;

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE PREFERRED EMBODIMENTS

The present invention is directed to the fabrication of high quality semiconductor structures having certain features described herein. As used herein, the term “semiconductor structures” will be used to refer to semiconductor structures, devices, integrated circuits and other useful items of significance. As will be explained in greater detail herein, fabrication of semiconductor structures according to principles of the present invention is assisted using laser energy, applied in a number of ways. By way of introduction, the present invention is directed to semiconductor structures having certain features, which will be generally described with reference to two examples. In a general description of a first example, semiconductor structures of interest have features which include a monocrystalline silicon substrate, an amorphous oxide material overlying the monocrystalline silicon substrate, a monocrystalline perovskite oxide material overlying the amorphous oxide material, and a monocrystalline compound semiconductor material overlying the monocrystalline perovskite oxide material. The semiconductor structure features may include a template layer between the monocrystalline perovskite oxide layer and the monocrystalline compound a semiconductor material. The semiconductor structure features may also include a buffer material of monocrystalline semiconductor material formed between the monocrystalline perovskite oxide material and the monocrystalline compound semiconductor material, and a template layer may also be formed between the monocrystalline perovskite oxide material and the buffer material.

In a general description of a second example, semiconductor structures of interest have features which include a monocrystalline substrate characterized by a first lattice constant and a monocrystalline insulator layer having a second lattice constant different than the first lattice constant overlying the monocrystalline substrate. An amorphous oxide layer is located between the monocrystalline substrate and the monocrystalline insulator layer and a monocrystalline compound semiconductor layer having a third lattice constant different than the first lattice constant overlies the monocrystalline insulator layer. The second lattice constant is selected to be equal to the third lattice constant or intermediate the first and third lattice constant. The semiconductor structure features may also include an optional template layer between the monocrystalline insulator layer and the monocrystalline compound semiconductor layer. Further, optional additional features may include a buffer layer between the monocrystalline insulator layer and the monocrystalline compound semiconductor layer.

With laser-assisted fabrication techniques according to principles of the present invention, high-quality semiconductor structures can be constructed with conventional equipment, using cost efficient techniques. As used herein, the term “high-quality” refers to active regions of monocrystalline compound semiconductor material having very low densities of crystallographic defects such as dislocations, anti phase domains, and stacking faults as well as very low impurity defect density levels approaching, in some instances, levels of less than 10¹⁵ parts per cubic centimeter.

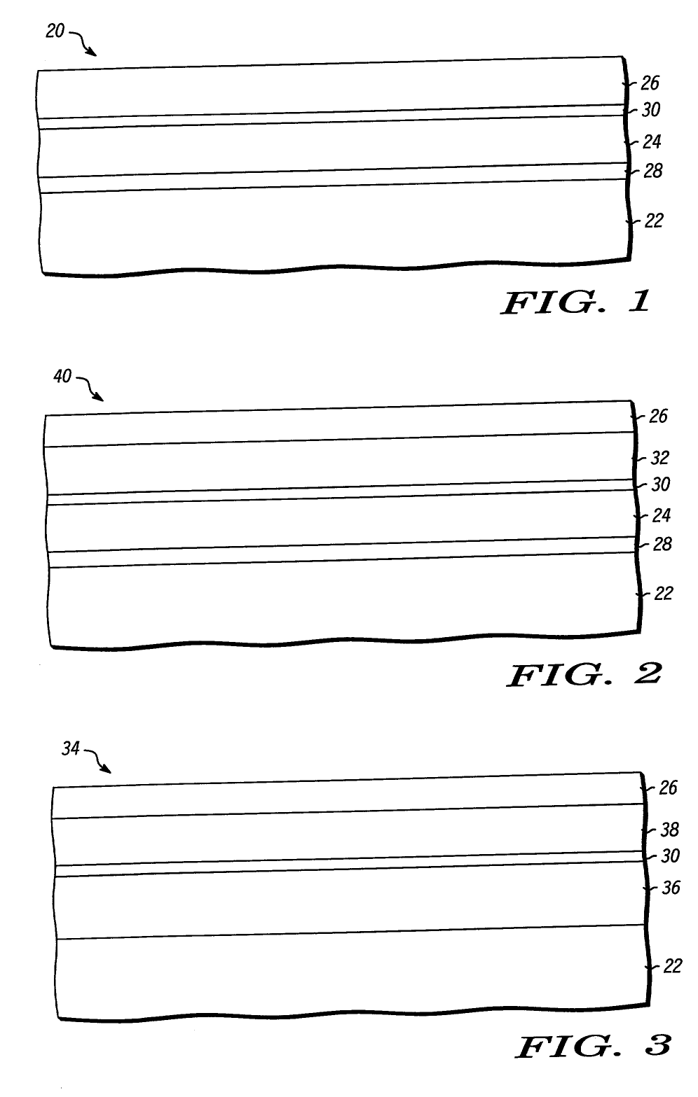

For purposes of illustration and not limitation, certain examples of semiconductor structures and devices, and their general method of fabrication, which benefit from the present invention, will now be given. Referring initially to FIG. 1, a schematic illustration of a semiconductor structure 20 is shown in cross section. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group HIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 mn. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700° C. The lattice structure of the resulting crystalline oxide exhibits a 45° rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen- phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45° rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 μm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The additional buffer layer 32, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g. layer 28 materials as described above) and accommodating buffer layer materials (e.g. layer 24 materials as described above). For example, amorphous layer 36 may include a combination of SiOₓ and Sr_{z}Ba_{1-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

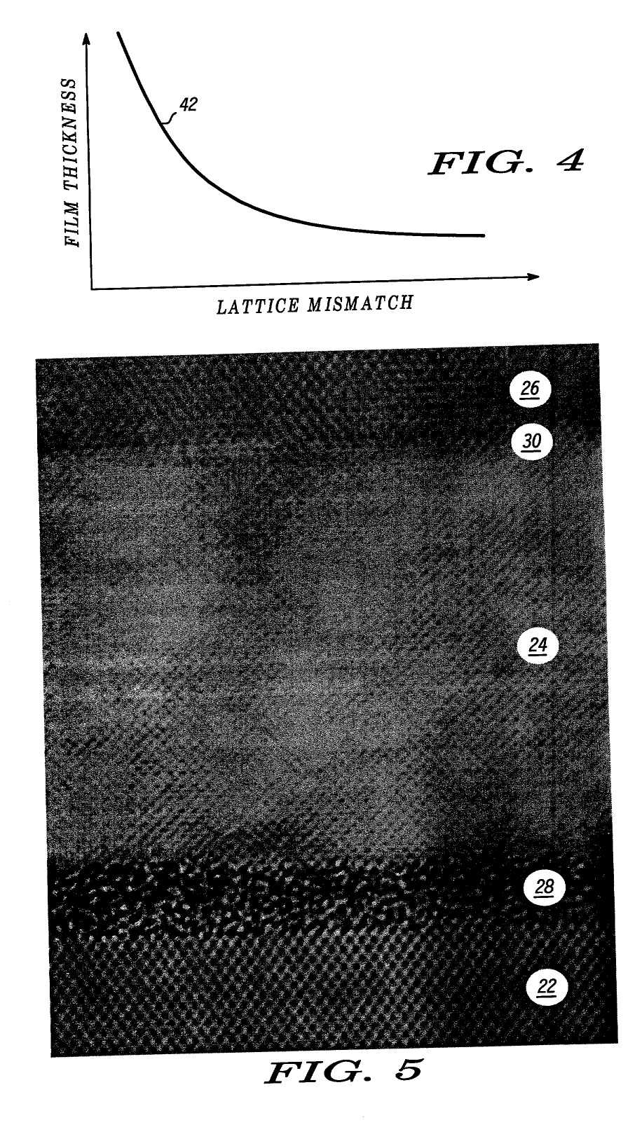

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

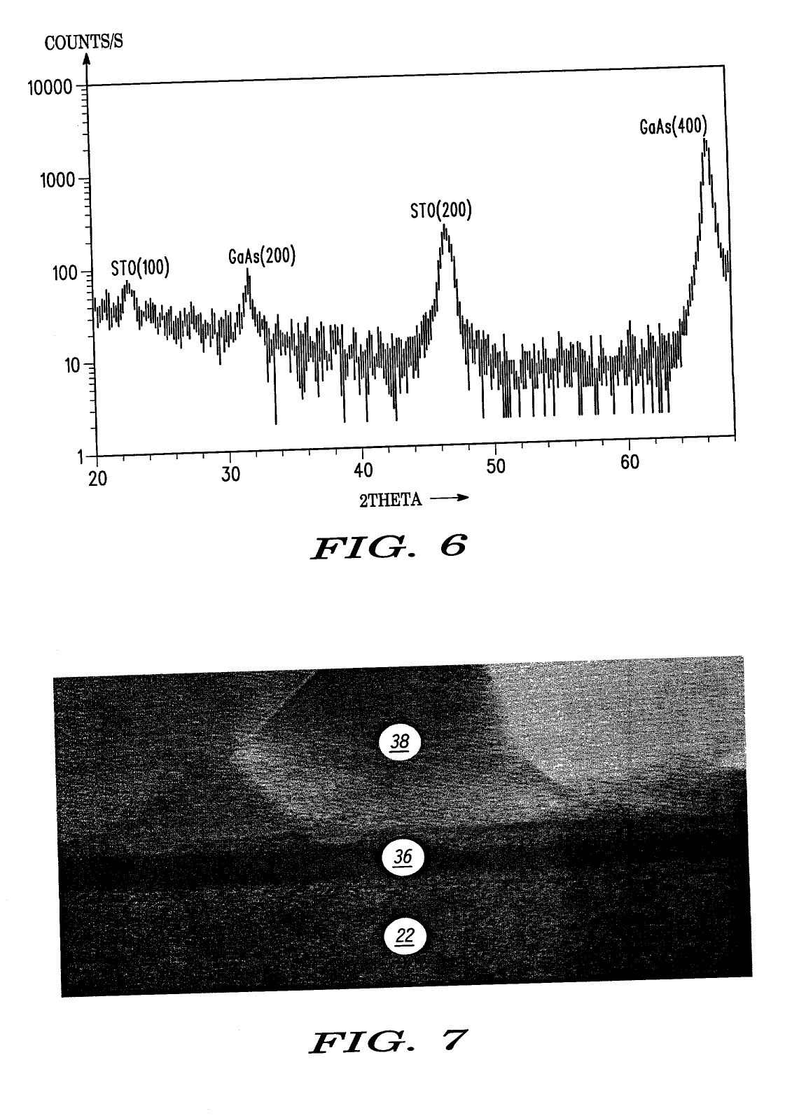

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

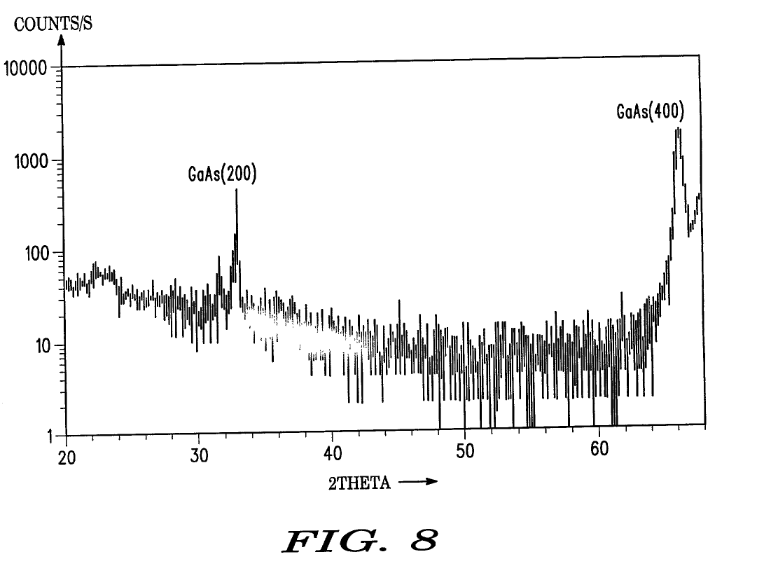

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50° indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

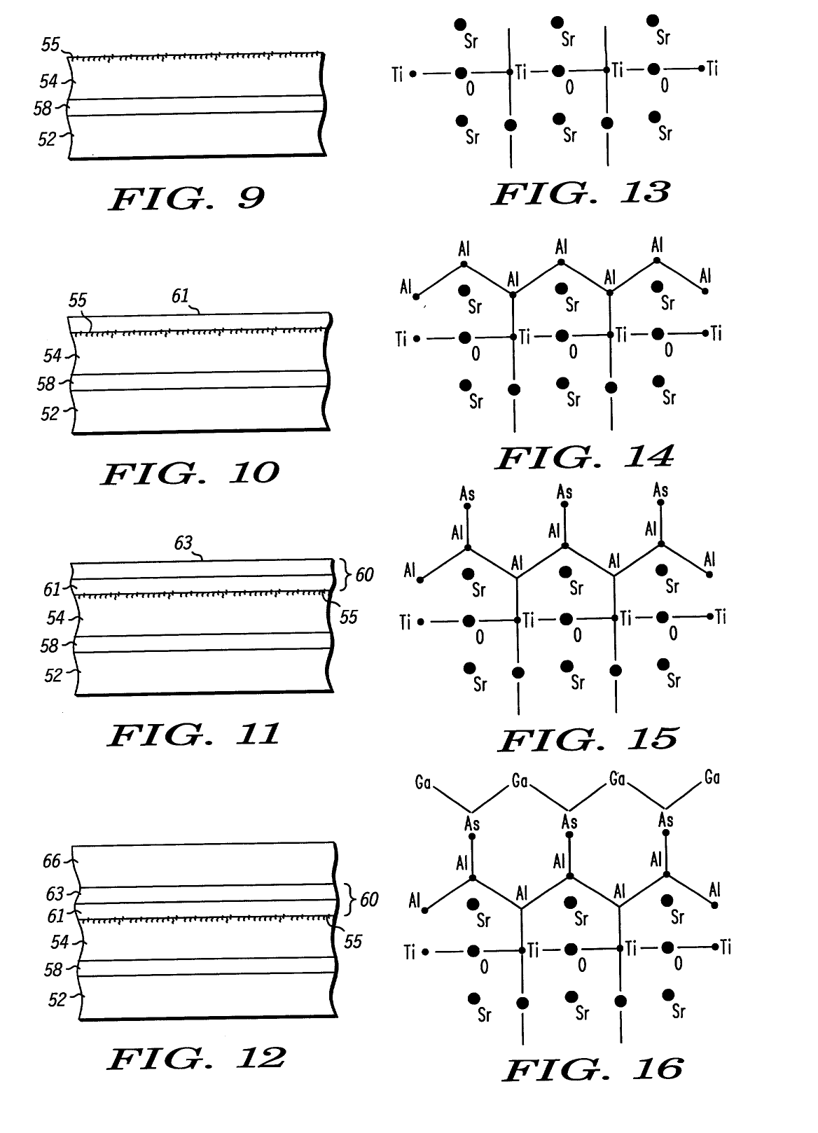

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, C VD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ^{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

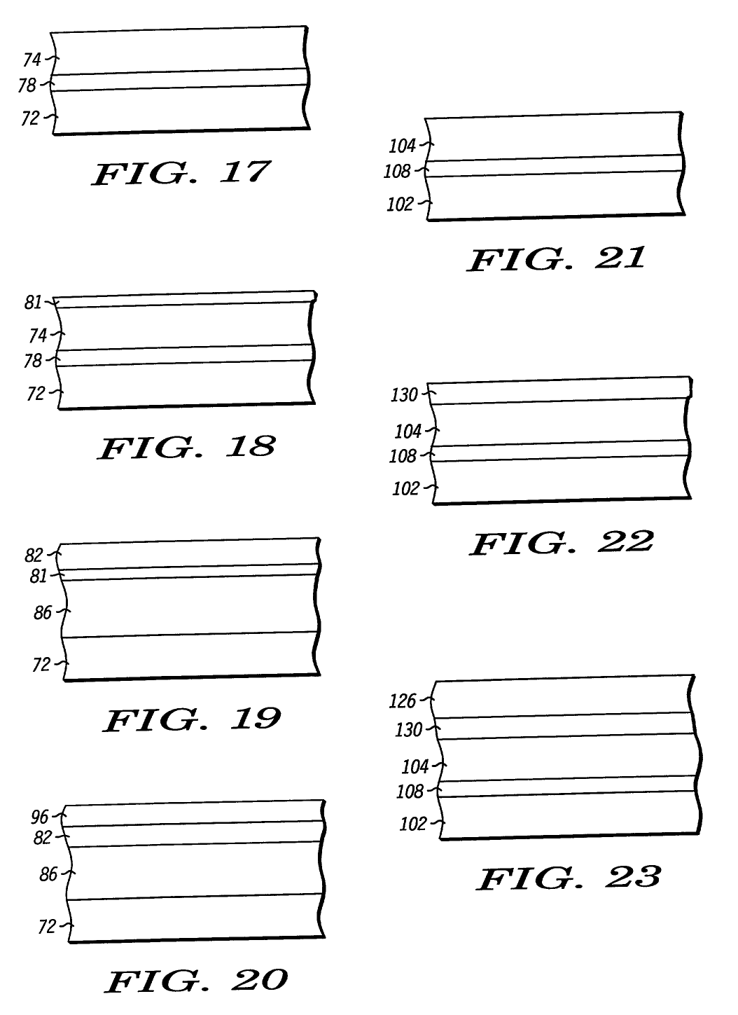

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphous the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂.

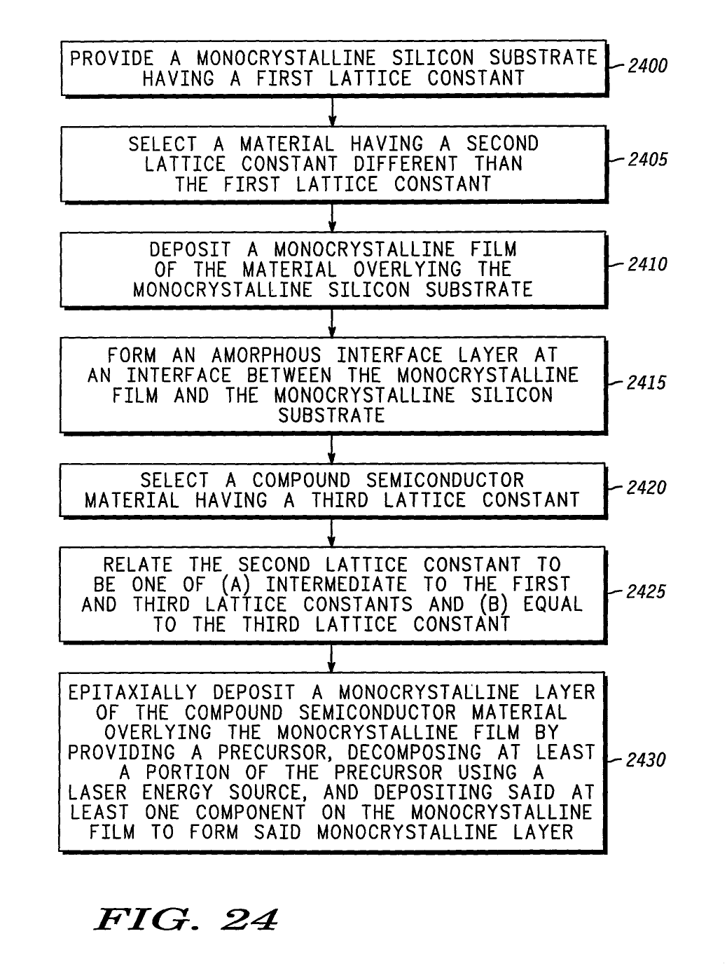

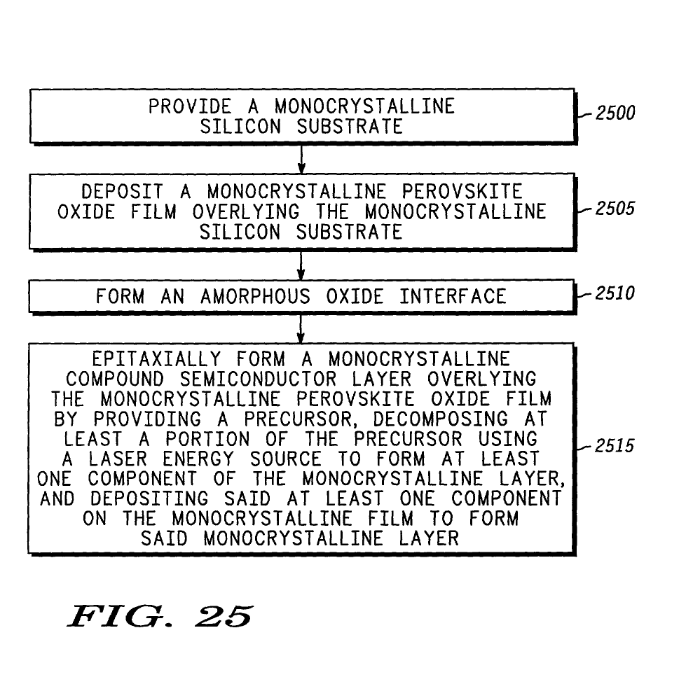

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention contemplates structures and methods for forming a compliant substrate which is used in the fabrication of semiconductor structures, devices and integrated circuits and the material layers suitable for fabricating those structures, devices, and integrated circuits. By using embodiments described herein, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In one example, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters. By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g., conventional compound semiconductor wafers).

As mentioned, with laser-assisted fabrication techniques according to principles of the present invention, “high-quality” semiconductor structures such as those described above can be fabricated by employing cost effective equipment and techniques. Heretofore, in order to achieve the low crystallographic defect density levels contemplated herein, the semiconductor structure was subjected to significant heating carried out at elevated temperatures. For example, low crystallographic defect density levels have been achieved by growing the device layers at elevated temperatures (e.g., above 700° C.) or by post growth rapid thermal annealing (e.g., 900° C. for 20 seconds).

Such heating, although beneficial for healing certain kinds of defects, gives rise to impurity control issues which, if not managed effectively, can lead to the degradation of operational performance. Further, as mentioned above, growth techniques carried out heretofore have employed the use of surfactants such as aluminum and other materials to facilitate nucleation during initial stages of growth. The use of surfactants, particularly in the presence of increased temperatures has been found to introduce levels of impurities that raise concerns about the operational performance of the completed semiconductor structure. The use of laser-assisted fabrication techniques according to principles of the present invention can be employed in place of surfactants during various stages of semiconductor structure fabrication. For example, according to principles of the present invention, laser energy is employed to modify the surface energy of the accommodating buffer layer in the various semiconductor structures described above to assist in the nucleation of monocrystalline semiconductor layer and to the accommodating buffer layer surface, without use of surfactants. Thus, ex-situ elements are employed with the monocrystalline material deposition systems, rather than employing surfactants to change the chemical structure and composition of underlying layers.

Laser-assisted techniques provide further advantages in the practical fabrication of commercially significant semiconductor structures. In one instance, practical constraints require that various components or layers of semiconductor structures be fabricated in different environments, and transported at certain times, from one environment to another. For example, it has been found convenient to employ STO material for the accommodating buffer layer, especially when substrates of monocrystalline silicon are used. This example utilizing STO material for the accommodating buffer layer, silicon for the moncrystalline substrate, and a monocrystalline compound semiconductor layer is given for purposes of illustration and not limitation, it being understood that the present invention pertains to other materials described herein, above.

Presently, molecular beam epitaxy is the preferred method of forming the STO accommodating buffer layer when substrates of monocrystalline silicon are employed. As those skilled in the art will appreciate, practical molecular beam epitaxy is carried out in a dedicated, special-purpose reactor chamber. Subsequent layer-by-layer growth on top of the STO accommodating buffer layer in practice requires that the semiconductor structure in process be removed from the molecular beam epitaxy reactor chamber. This usually results in the partially formed semiconductor structure being exposed to ambient moisture, for example. Prior to commencing growth of the monocrystalline compound semiconductor material, a laser, such as a continuous wave, frequency doubled Ar+laser (Argon high energy laser) is employed to preclean the STO accommodating buffer layer surface. Other types of lasers (such as Ar—F, Ar—Cl and Xe—F) are also contemplated by the present invention, although it is generally preferred that the lasers employed operate in the ultraviolet regime. Preferably, the same laser treatment is also used to desorb any absorbed H₂O or OH groups that may have formed on the surface of the STO accommodating buffer layer since its removal from the molecular beam epitaxy reactor chamber.

Following the precleaning and desorbing steps, and without transport to another environment, the partially formed semiconductor structure is prepared for monocrystalline compound semiconductor material growth. After formation of any desired template layer, a laser, preferably the same continuous wave, frequency doubled Ar+laser is employed to energize the surface of the partially formed semiconductor structure as growth of the monocrystalline compound semiconductor material is initiated. Laser irradiation at this point in the fabrication process promotes the surface atoms into higher energy states, such that two-dimensional growth is realized without the need of surfactant materials. In this manner, three-dimensional or “island” growth can be readily eliminated.

As fabrication continues, the monocrystalline compound semiconductor material layer increases in thickness at a controlled rate. At a thickness less than the critical thickness for stress relief by dislocation formation, a laser (preferably the same laser as that used above in the precleaning and desorbing steps) is employed to selectively heat the underlying STO accommodating buffer layer. It is preferred that the single crystal STO material formed by molecular beam epitaxy is left unaltered until this latter stage in the fabrication process. Rather than subjecting the partially formed or fully formed semiconductor structure to rapid thermal annealing or other gross heating step, the continuous wave, frequency doubled Ar+laser is employed to completely amorphous the STO accommodating buffer layer. In carrying out this step in the fabrication process it is preferred that the laser energy output be set to a level above the bandgap energy of silicon but below the bandgap energy of the monocrystalline compound semiconductor material, so that the underlying silicon substrate selectively absorbs most, if not all of the heat energy resulting from this amorphization step. When the STO accommodating buffer layer is sufficiently amorphized, growth of the monocrystalline compound semiconductor material continues until the desired thickness is achieved. Laser operation can also be employed to anneal the monocrystalline compound semiconductor material as well as selectively activating organometallics present in the semiconductor structure, further eliminating the need for gross thermal activation.

As seen from the above description, the use of laser-assisted fabrication techniques can reduce overall heating of the semiconductor structure by eliminating rapid thermal annealing or other gross heating methods usually associated with amorphization. Further, the use of laser-assisted fabrication techniques selectively directs the thermal effects of the amorphizing energization to a portion of the semiconductor structure which most efficiently tolerates heating. Thus, for example, heating can be directed to portions of the semiconductor structure where impurity controls are most readily implemented.

Laser-assisted fabrication according to principles of the present invention can also be employed for highly localized annealing to heal highly localized regions without requiring gross thermal treatment. Those skilled in the art will appreciate practical advantages afforded by selective pin-point operation according to the present invention, for example, where the semiconductor structure already contains devices which cannot tolerate high temperatures. Further, laser radiation energy can be applied with precision with regard to depth, as well as the two-dimensional “footprint” or surface area of the material being treated. With the present invention, highly selective annealing of monocrystalline materials can be readily achieved by directly, i.e., selectively heating the targeted areas.

Laser-assisted semiconductor structure and device fabrication can also receive benefit where decomposition is employed, particularly precursor decomposition employed for layer growth. In one example, a laser, preferably the same laser used in the precleaning and desorbing steps described above is employed to crack or decompose precursors for layer growth. Examples of such precursors include AsH₃, and Ga(C₂H₅)₃ used for certain types of monocrystalline materials. With laser assistance, processes (such as CVD, MOCVD, and MBE) which require activation of precursor materials by incident energy can be carried out at lower substrate temperatures. With the present invention, incident energy can be directly inputted to the precursor materials by highly localized laser irradiation, rather than gross thermal activation using rapid thermal annealing or other techniques. Laser-assisted decomposition can occur with or without the other laser-assisted fabrication techniques described herein.

Laser-assisted precursor deposition according to principles of the present invention also enables selective deposition of the monocrystalline material over preselected regions of the underlying semiconductor structure. Deposition can be controlled with the exacting precision associated with high quality laser irradiation processes. In many instances, selective deposition can be carried out according to the present invention without requiring the use of a mask device. For example, ultraviolet lasers can be operated at a wave length sufficient to produce structures at a resolution of 0.1 microns. Selective growth at exacting resolutions required for commercially significant devices results, in part, from the ability to selectively heat the surface on which deposition is to occur. Increased speed of fabrication, especially in the absence of a masking device can be readily achieved using available cost effective devices and techniques. Depth of surface heating can also be readily controlled using laser-assisted selected deposition according to the present invention. In this manner, an optimally minimal heat capacity can be imparted to the surface on which deposition takes place, so as to ensure proper surface temperatures despite small scale transient thermal effects. Depth of selective laser-assisted heating according to other aspects of the present invention further aids in assuring pure crystalline growth at highly localized micro environments on portions of a substrate surface.

The present invention also provides significant cost saving advantages, increased impurity control and increased speed of fabrication where only minor areas on a substrate surface require a particular growth layer. By utilizing laser-assisted selected deposition according to the present invention, layer growth can be directly formed in situ at the locations needed, thereby avoiding gross, surface-wide layer formation followed by removal of unwanted major portions carried out in external processes, often times in foreign environments. In addition to the fabrication of small structures on a much larger substrate, laser-assisted selective deposition according to principles of the present invention finds immediate application in the field of semiconductor wafer repair. For example, gaps in circuit traces can be readily repaired using fast, economical laser-assisted selected deposition according to the present invention, with minimal risk to surrounding structures carried on the wafer.

With laser-assisted selective deposition according to the present invention, selective localized cracking or decomposition of deposition precursors also aids in the selective deposition process. Laser-assisted decomposition can be carried out on a wide variety of precursor materials used in chemical vapor deposition processes. Examples of such precursor materials include trimethylene Galium, trimethylene aluminum, trimethylene indium, indium chloride and Galium chloride. Further, laser-assisted fabrication techniques can also be readily employed with molecular beam epitaxy utilizing, for example an As₄ precursor and with gas source molecular beam epitaxy utilizing phosphine gas as a precursor supplying phosporous.

As can be seen from the above, the present invention provides a process for fabricating a semiconductor structure, utilizing a monocrystalline silicon substrate having a first lattice constant. Referring now to FIG. 24, a flow chart shows some steps of a process for fabricating a semiconductor, using the techniques described in this disclosure. Some steps that have been described herein above and some steps that are obvious to one of ordinary skill in the art are not shown in the flow chart, but would be used to fabricate the semiconductor. At step 2400, a monocrystalline silicon substrate is provided, meaning that the substrate is prepared for use in equipment that is used in the next step of the process. A monocrystalline film is applied so as to overlay the monocrystalline silicon substrate. The film is selected at step 2405 from a material which, when properly oriented, has a second lattice constant and crystalline structure compatible with deposition on the monocrystalline silicon substrate. The monocrystalline film is deposited at step 2410 so as to have a thickness less than the thickness of the material that would result in strain-induced defects, with strain arising because the first lattice constant is different from the second lattice constant. At step 2415, an amorphous interface layer is formed at an interface between the monocrystalline film and monocrystalline silicon substrate and has a thickness sufficient to relieve the strain in the monocrystalline film. At step 2420, a compound semiconductor is selected from material having a third lattice constant which, when properly oriented, is compatible with deposition on the monocrystalline film as a monocrystalline compound semiconductor layer. The second lattice constant is related to the other lattice constants at step 2425 to be one of (a) intermediate to the first and third lattice constants and (b) equal to the third lattice constant. The monocrystalline layer of the compound semiconductor material is epitaxially deposited at step 2430 by providing a precursor, and selectively heating the monocrystalline film with a laser energy source, preferably an ultraviolet laser to achieve deposition. At least a portion of the precursor to forming the monocrystalline layer is decomposed at this step 2430 by the laser energy source so as to form at least one component of the monocrystalline layer. Laser energy heating of the monocrystalline film and selected decomposition of the precursor at this step 2430 cooperate to deposit the decomposition component on the monocrystalline film so as to form the monocrystalline layer. The laser energy source can also be used for precleaning and/or annealing the various surfaces of the structure, during fabrication, if desired.

Referring now to FIG. 24, in another example, a flow chart shows some steps of laser-assisted fabrication according to principles of the present invention that can be employed to fabricate a semiconductor structure, using the techniques described in this disclosure. Some steps that have been described herein above and some steps that are obvious to one of ordinary skill in the art are not shown in the flow chart, but would be used to fabricate the semiconductor. At step 2500, a monocrystalline silicon substrate is provided, meaning that the substrate is prepared for use in equipment that is used in the next step of the process. At step 2505, a monocrystalline perovskite oxide film is deposited on a monocrystalline silicon substrate. The film is deposited so as to have a thickness less than the thickness of the material that would result in strain-induced defects. At step 2510, an amorphous oxide interface layer containing at least silicon and oxygen is formed at an interface between the monocrystalline perovskite oxide film and the monocrystalline silicon substrate. A monocrystalline compound semiconductor layer is epitaxially formed over the monocrystalline perovskite oxide film at step 2515 by utilizing a precursor. The monocrystalline perovskite oxide film is selectively heated using a laser energy source which also decomposes at least a portion of the precursor at the region of oxide film heating. The laser-assisted decomposition and heating cooperate in the deposition of a precursor constituent on the perovskite oxide film at this step 2515. A laser energy source, preferably the same laser energy source as that used for selective decomposition and heating can also be advantageously employed for precleaning and/or annealing of the structure surfaces, during fabrication.

Laser-assisted fabrication techniques according to principles of the present invention are advantageously employed in so-called “indirect” epitaxial growth processes. When fabrication of a semiconductor structure or device is carried out using an indirect process, material for the desired layer is obtained by the decomposition of a precursor compound containing the desired layer material. Decomposition occurs at or immediately adjacent to the substrate surface on which growth is to occur. For example, growth of a silicon layer using indirect layer processes attains the silicon atoms by decomposition of a precursor vapor of a silicon compound of the substrate surface. Examples include the hydrogen reduction of SiCl₄SiBr₄, SiHCl₃ and the pyrolysis of SiH₄. It is believed that silicon is formed on a substrate surface by either a surface-controlled reaction or by a defusion of the desired precursor constituent in the form of atoms, groups of atoms or overcooled droplets deposited on the substrate surface by defusion.

Surface controlled reactions require mass transfer of the necessary reactant(s) to the substrate surface followed by adsorption of the reactant(s) onto the substrate surface. Selectively controlled laser assistance according to the present invention aids in the reaction or series of reactions which occur on the substrate surface, as well as desorption of the bi-product molecules. Depending on the individual processes involved, the overall growth rate can be improved with laser-assisted fabrication according to principles of the present invention. As will be appreciated, in any of the steps involved in surface controlled growth, processes are strongly dependent on temperature. With laser-assisted fabrication techniques according to principles of the present invention, fabrication can proceed at relatively lower growth temperatures.

Considering briefly the alternative process, that of deposition by diffusion, laser-assisted fabrication techniques can again be advantageously employed to produce more perfect epitaxially layers. Components of the monocrystalline layer to be grown are freed from the precursor compound material, usually in the form of a gas or less often a solid form, adjacent to the substrate. The monocrystalline constituents undergo transport through the precursor layer, governed by diffusion properties. After reaching the substrate, the monocrystalline constituents are mobile and are free for preferential alignment with the substrate crystalline structure. If the growth temperature on the substrate surface varies substantially, the nucleation rate will in turn be affected. Laser-assisted fabrication techniques according to principles of the present invention are advantageously employed for more exacting control of the growth temperature.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A process for fabricating a semiconductor structure comprising:
providing a monocrystalline silicon substrate having a first lattice constant;
selecting a material that when properly oriented has a second lattice constant and crystalline structure such that the material can be deposited as a monocrystalline film overlying the monocrystalline silicon substrate, the second lattice constant being different than the first lattice constant;
depositing a monocrystalline film of the material overlying the monocrystalline silicon substrate, the film having a thickness less than a thickness of the material that would result in strain-induced defects, the monocrystalline film being strained because the first lattice constant is different than the second lattice constant;
forming an amorphous interface layer at an interface between the monocrystalline film and the monocrystalline silicon substrate, the amorphous interface layer having a thickness sufficient to relieve the strain in the monocrystalline film;
selecting a compound semiconductor material having a third lattice constant that is different than the first lattice constant and that when properly oriented can be deposited on the monocrystalline film as a monocrystalline compound semiconductor layer;
relating the second lattice constant to be one of (a) intermediate to the first and third lattice constants and (b) equal to the third lattice constant;
epitaxially depositing a monocrystalline layer of the compound semiconductor material overlying the monocrystalline film by
providing a precursor,
decomposing at least a portion of the precursor using a laser energy source to form at least one component of the monocrystalline layer, and
depositing said at least one component on the monocrystalline film to form said monocrystalline layer.

2. The process of claim 1 further comprising the step of precleaning at least a portion of the surface of at least one of (a) monocrystalline silicon substrate (b) monocrystalline film and (c) amorphous interface layer by irradiating with a laser radiation source.

3. The process of claim 2 wherein the precleaning step comprises precleaning the monocrystalline film with a laser radiation source prior to deposition of the monocrystalline layer of the compound semiconductor material.

4. The process of claim 1 wherein the decomposing step comprises decomposing with an ultraviolet laser radiation source.

5. The process of claim 1 wherein the laser energy also desorbs moisture from the surface irradiated.

6. The process of claim 1 further comprising the step of exciting an initial portion of the compound semiconductor material deposited on the monocrystalline film with the laser radiation source to promote nucleation and two-dimensional growth of the compound semiconductor material while avoiding the use of surfactants.

7. The process of claim 1 further comprising the step of irradiating the monocrystalline film with a laser radiation source so as to convert the monocrystalline film to substantially completely amorphous material.

8. The process of claim 7 wherein the step of irradiating the monocrystalline film is carried out before a thickness of the compound semiconductor material exceeds a critical thickness less than a thickness of the material that would result in strain-induced defects.

9. The process of claim 1 further comprising the step of irradiating the monocrystalline layer so as to anneal the compound semiconductor material.

10. The process of claim 1 wherein the step of epitaxially depositing a monocrystalline layer of the compound semiconductor material overlying the monocrystalline film is carried out utilizing chemical vapor deposition at least one with volatile chemical precursor to growth of the compound semiconductor material, with the decomposing step comprising the step of irradiating at least a portion of the at least one precursor with a laser radiation source so as to decompose the portion thereby enabling growth of the compound semiconductor material at a lower temperature.

11. The process of claim 1 wherein the step of epitaxially depositing a monocrystalline layer of the compound semiconductor material overlying the monocrystalline film is carried out with the step of irradiating a preselected portion of the monocrystalline film with a laser radiation source so as to excite a preselected region of the monocrystalline film so as to selectively accelerate growth of the compound semiconductor material in the portion irradiated.

12. The process of claim 11 wherein the step of epitaxially depositing a monocrystalline layer of the compound semiconductor material overlying the monocrystalline film is carried out utilizing chemical vapor deposition with a precursor to growth of the compound semiconductor material, with the decomposing step comprising irradiating a preselected portion of the precursor with a laser radiation source so as to selectively decompose the precursor portion irradiated thereby initiating selective growth of the compound semiconductor material in the portion irradiated.

13. The process of claim 1 further comprising:
exciting with the laser radiation source, so as to render more reactive, at least a portion of the monocrystalline film,
continuing irradiation with the laser radiation source so as to excite an initial portion of the compound semiconductor material deposited on the monocrystalline film to promote nucleation and two-dimensional growth of the compound semiconductor material while avoiding the use of surfactants, and
after carrying out said continuing irradiation step, increasing the power of said laser radiation source so as to heal defects in an initial portion of the compound semiconductor material being deposited.

14. The process of claim 1 further comprising forming a first template layer overlying the monocrystalline silicon substrate to nucleate depositing the monocrystalline film.

15. The process of claim 14 further comprising forming a second template layer overlying the monocrystalline film to nucleate epitaxially depositing the monocrystalline layer.

16. A process for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate; and
epitaxially forming a monocrystalline compound semiconductor layer overlying the monocrystalline perovskite oxide film by
providing a precursor,
decomposing at least a portion of the precursor using a laser energy source to form at least one component of the monocrystalline layer, and
depositing said at least one component on the monocrystalline film to form said monocrystalline layer.

17. The process of claim 16 further comprising the step of precleaning at least a portion of the surface of at least one of (a) monocrystalline silicon substrate (b) monocrystalline perovskite oxide film and (c) amorphous oxide interface layer by irradiating with a laser radiation source.

18. The process of claim 17 wherein the precleaning step comprises precleaning the monocrystalline film with a laser radiation source prior to deposition of the monocrystalline layer of the compound semiconductor material.

19. The process of claim 18 wherein the precleaning step comprises precleaning with an ultraviolet laser radiation source.

20. The process of claim 17 wherein the precleaning step comprises desorbing moisture from the surface irradiated.

21. The process of claim 16 further comprising the step of exciting an initial portion of the compound semiconductor material deposited on the monocrystalline film with the laser radiation source to promote nucleation and two-dimensional growth of the compound semiconductor material while avoiding the use of surfactants.

22. The process of claim 16 further comprising the step of irradiating the monocrystalline film with a laser radiation source so as to convert the monocrystalline film to substantially completely amorphous material.

23. The process of claim 22 wherein the step of irradiating the monocrystalline film is carried out before thickness of the compound semiconductor material exceeds a critical thickness less than a thickness of the material that would result in strain-induced defects.

24. The process of claim 16 further comprising the step of irradiating the monocrystalline layer so as to anneal the compound semiconductor material.

25. The process of claim 16 wherein the step of epitaxially depositing a monocrystalline layer of the compound semiconductor material overlying the monocrystalline film is carried out utilizing chemical vapor deposition with a volatile chemical precursor to growth of the compound semiconductor material, with the decomposing step comprising the step of irradiating at least a portion of the precursor with a laser radiation source so as to decompose the precursor portion thereby enabling selective growth of the compound semiconductor material at a lower temperature.

26. The process of claim 16 further comprising the step of laser irradiating so as to excite a preselected region of the monocrystalline film and to selectively accelerate growth of the compound semiconductor material in the region of laser radiation.

27. The process of claim 16 wherein the step of epitaxially depositing a monocrystalline layer of the compound semiconductor material overlying the monocrystalline film is carried out utilizing chemical vapor deposition with a precursor to growth of the compound semiconductor material, with the process further comprising the step of irradiating preselected portions of the precursor and the monocrystalline film with a laser radiation source so as to selectively heat the monocrystalline film while decomposing the precursor portion irradiated, thereby facilitating selective growth of the compound semiconductor material in the region of laser radiation.

28. The process of claim 16 further comprising:
exciting at least a portion of the monocrystalline film with the laser radiation source, so as to render the portion more reactive;
continuing irradiation with the laser radiation source so as to excite an initial portion of the compound semiconductor material deposited on the monocrystalline film to promote nucleation and two-dimensional growth of the compound semiconductor material while avoiding the use of surfactants; and
after carrying out said continuing irradiation step, increasing the power of said laser radiation source so as to heal defects in the compound semiconductor material being deposited.

29. The process of claim 16 further comprising forming a first template layer overlying the monocrystalline silicon substrate to nucleate depositing the monocrystalline film.

30. The process of claim 29 further comprising forming a second template layer overlying the monocrystalline film to nucleate epitaxially depositing the monocrystalline layer.

31. The process of claim 16 further comprising forming a first template layer overlying the monocrystalline silicon substrate to nucleate depositing the monocrystalline perovskite oxide film.

32. The process of claim 31 further comprising forming a second template layer overlying the monocrystalline perovskite oxide film to nucleate epitaxially depositing the monocrystalline compound semiconductor layer.
